(19) United States
(12) Patent Application Publication
(10) Pub. No.: US 2015/0001728 A1
(43) Pub. Date: Jan. 1, 2015

(54) PRE-TREATMENT METHOD FOR METAL-OXIDE REDUCTION AND DEVICE FORMED

(71) Applicant: TAIWAN SEMICONDUCTOR MANUFACTURING COMPANY, LTD., Hsinchu (TW)

(72) Inventors: Li CHEN, New Taipei City (TW); Jyh-Nan LIN, Hsinchu City (TW); Chin-Feng SUN, Zhubei City (TW); Po-Hsiung LEU, Lujhu Township (TW); Ding-I LIU, Hsinchu City (TW)

(21) Appl. No.: 13/927,570

(22) Filed: Jun. 26, 2013

(51) Int. Cl. H01L 21/768; H01L 23/48

(52) U.S. Cl. CPC H01L 21/76885; H01L 23/481
USPC 257/773; 438/618

(57) ABSTRACT

A method of forming a semiconductor device, the method includes performing, in a first module, a remote plasma treatment on a wafer to remove an oxide layer from the wafer by a reduction reaction. The method further includes transferring the pre-treated wafer from the first module to a second module under a vacuum. The method further includes forming, in the second module, an etch stop layer over the wafer.

### BACKGROUND

Semiconductor devices include interconnect structures to provide electrical connections between various active devices in the semiconductor device. An interconnect structure includes conductive lines and vias surrounded by an insulating material to reduce the risk of electrical signals unintentionally transitioning from one conductive line or via to an adjacent conductive line or via. Electrical resistance between connected conductive lines or vias on different metal levels is a factor in determining power consumption and speed of the semiconductor device. As the electrical resistance between connected conductive lines or vias increases, power consumption increases and the speed of the semiconductor device decreases.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. It is emphasized that, in accordance with standard practice in the industry various features may not be drawn to scale and are used for illustration purposes only. In fact, the dimensions of the various features in the drawings may be arbitrarily increased or reduced for clarity of discussion.

FIGS. 1A-1D are cross sectional diagrams of a wafer at various stages of production in accordance with one or more embodiments;

FIG. 2 is a schematic diagram of a remote plasma treatment apparatus used to reduce a metal oxide layer on a wafer in accordance with one or more embodiments;

FIG. 3 is a graph of a dielectric constant of an inter-metal dielectric (IMD) layer in accordance with one or more embodiments;

FIG. 4 is a graph of an adhesion force between an IMD layer and an etch stop layer in accordance with one or more embodiments;

FIG. 5 is a graph of a carbon concentration depth profile of a wafer in accordance with one or more embodiments;

FIG. 6 is a flow chart of a method of reducing a metal oxide layer on a wafer in accordance with one or more embodiments; and

FIG. 7 is a block diagram of an apparatus for implementing the method of FIG. 6 in accordance with one or more embodiments.

### DETAILED DESCRIPTION

The following disclosure provides many different embodiments, or examples, for implementing different features of the invention. Specific examples of components and arrangements are described below to simplify the present disclosure. These are examples and are not intended to be limiting.

A dielectric constant of the insulating material also impacts an RC delay of the semiconductor device. An adhesion strength between layers of the semiconductor device also impacts device reliability and longevity.

In situations where a metal is used to form the conductive lines or vias, oxide layers form on surfaces of the metal line or via exposed to air or water due to a chemical oxidation reaction between the metal and oxygen in a surrounding environment. Metal oxides provide a higher electrical resistance between connected metal lines or vias than elemental metal or metal alloys.

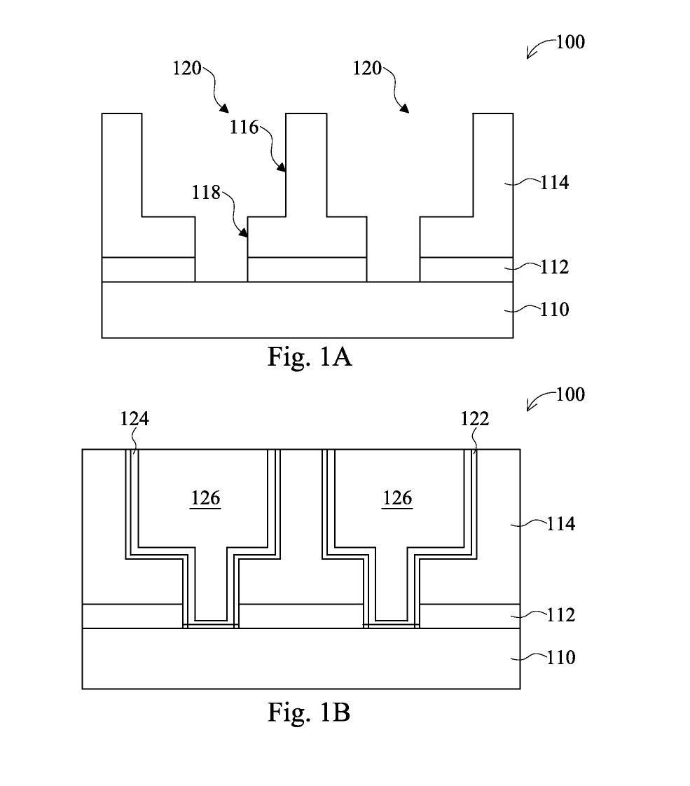

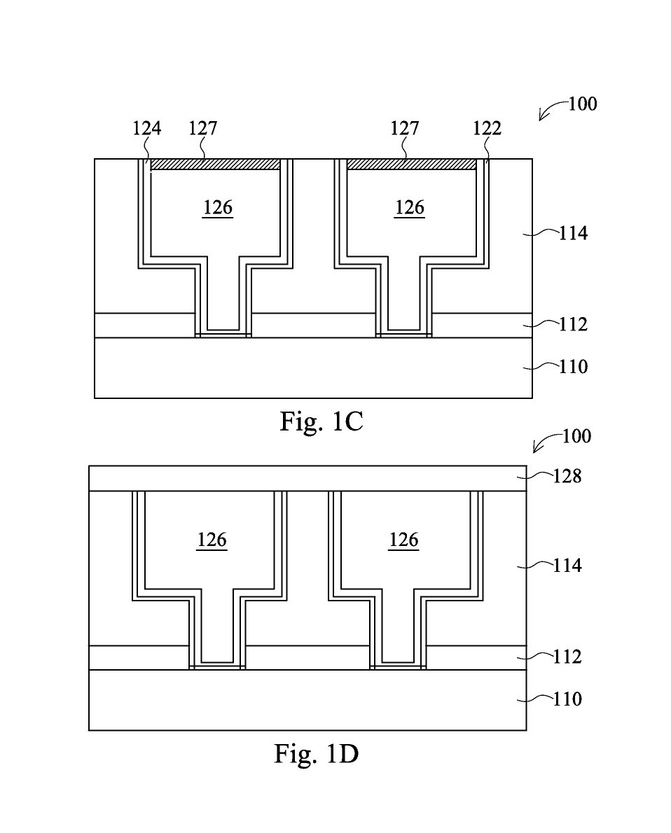

FIG. 1A is a cross sectional diagram of a wafer 100 at a first stage of production in accordance with one or more embodiments. Wafer 100 includes a substrate 110 and a first etch stop layer 112 over the substrate. An inter-metal dielectric (IMD) layer 114 is over first etch stop layer 112. Two openings 120 are in each of IMD layer 114 and first etch stop layer 112. Each opening 120 includes an upper section 116 and a lower section 118. In some embodiments, upper section 116 is used to form a conductive line and lower section 118 is used to form a conductive via.

Substrate 110 is used to form a semiconductor device. In some embodiments, active devices are formed in or on substrate 110. In some embodiments, substrate 110 is a semiconductor substrate, for example, a silicon substrate with or without an epitaxial layer; a silicon-on-insulator (SOI) substrate; an alloy substrate, such as silicon-germanium (SiGe); or another suitable substrate. The semiconductor device includes devices comprising, for example, transistors, diodes, resistors, capacitors, inductors or other active or passive circuitry. In some embodiments, a conductive region is formed in substrate 110.

First etch stop layer 112 is used to control an end point of a process of forming openings 120. In some embodiments, first etch stop layer 112 comprises silicon oxide, silicon nitride, silicon carbide, silicon oxynitride, or other suitable etch stop materials. In some embodiments, a dielectric constant (k) is greater than 4.0. In some embodiments, a thickness of first etch stop layer 112 ranges from about 10 angstroms (\acute{Å}) to about 1000 \acute{Å}. In some embodiments, first etch stop layer 112 is a multi-layer etch stop layer. In some embodiments, at least one of the layers of the multi-layer etch stop layer comprises tetraethyl orthosilicate (TEOS). In some embodiments, first etch stop layer 112 is formed by low-pressure chemical vapor deposition (LPCVD), atmospheric-pressure CVD (APCVD), plasma-enhanced CVD (PECVD), physical vapor deposition (PVD), sputtering, or another suitable formation technique.

IMD layer 114 is a low-k dielectric material. Low-k means IMD layer 114 has a dielectric constant (k) of 3.0 or less. In some embodiments, IMD layer 114 has a dielectric constant less than 2.5 and is called an extreme low-k (ELK) material. In some embodiments, IMD layer 114 has a dielectric constant less than 2.0 and is called a porous low-k material. In some embodiments, IMD layer 114 has a dielectric constant less than 1.5. In some embodiments, IMD layer 114 comprises carbon-doped silicon dioxide. In some embodiments, IMD layer 114 comprises organic dielectrics, inorganic dielectrics, porous dielectric material, organic polymers, organic silica glass, fluorosilicate glass (FSG), hydrogen silsesquioxane (HSQ) material, methyl silsesquioxane (MSQ) material, a porous organic material, or another suitable low-k material.

In some embodiments, IMD layer 114 is a single layer structure. In some embodiments, IMD layer 114 is a multilayer structure. In some embodiments where IMD layer 114 comprises carbon-doped silicon dioxide, a ratio by weight of carbon to silicon ranges from about 0.3 to about 0.8.

In some embodiments, IMD layer 114 is formed by CVD, plasma enhanced CVD (PECVD), spin-on coating, or another suitable formation technique.

Openings 120 are shown as an example of a dual damascene opening. In some embodiments, openings 120 include only a trench opening, only a via opening or another suitable type of opening. In some embodiments, openings 120 are formed using a “trench-first” patterning process or a “via-first” patterning process. In some embodiments, openings 120 are formed by patterning a photoresist layer over IMD layer 114 and etching the IMD layer to create the openings. First etch stop layer 112 is used to provide an end point for the etching process. A portion of opening 120 through first etch stop layer 112 is formed in a separate etching process from the etching process used on IMD layer 114.

FIG. 1B is a cross sectional diagram of wafer 100 at a second stage of production in accordance with one or more embodiments. A barrier layer 122 is formed on sidewalls and a bottom edge of openings 120. A seed layer 124 is formed on sidewalls of barrier layer 122 and along a bottom edge of openings 120. A conductive layer 126 is formed in openings 120 to substantially fill a remaining portion of the openings defined by seed layer 124.

Barrier layer 122 is disposed to prevent diffusion of conductive layer 126 into IMD layer 114. In some embodiments, barrier layer 122 is disposed only on the sidewalls of opening 120. In some embodiments, barrier layer 122 is a multilayer composition. In some embodiments, barrier layer 122 has a thickness ranging from about 10 \acute{Å} to about 300 \acute{Å}. In some embodiments, liner layer 122 comprises tantalum (Ta), titanium (Ti), nitrides of Ta or Ti, or other suitable materials.

In some embodiments, barrier layer 122 is formed by physical vapor deposition (PVD), atomic layer deposition (ALD) or another suitable formation process. In some embodiments, liner layer 122 is formed along the bottom edge of openings 120 as well as on the sidewalls of the openings. Liner layer 122 is removed from the bottom edge of openings 120 prior to forming seed layer 124. In some embodiments, overhangs are formed at corners of openings 120 during formation of liner layer 122. The overhangs are removed prior to formation of seed layer 124. In some embodiments, the overhangs are removed using an etching process, such as a plasma etching process.

Seed layer 124 is used to provide a base on which to form conductive layer 126. In some embodiments, seed layer 124 has a thickness ranging from about 50 \acute{Å} to about 1000 \acute{Å}. In some embodiments, seed layer 124 is an alloy layer including a main component and an additive. In some embodiments, the main component is copper (Cu) or another suitable main component material. In some embodiments, the additive comprises manganese (Mn), aluminum (Al), Ti, niobium (Nb), chromium (Cr), vanadium (V), yttrium (Y), technetium (Tc), rhenium (Re), cobalt (Co), or other suitable additive materials. In some embodiments, seed layer 124 is formed using PVD, CVD, PECVD, LPCVD, or other suitable formation techniques.

Conductive layer 126 is used to provide electrical connections between various elements of semiconductor devices on wafer 100. Conductive layer 126 comprises a main component which is the same as the main component of seed layer 124. In some embodiments, the main component of conductive layer 126 is copper. In some embodiments where seed layer 124 comprises an additive, conductive layer 126 comprises a different additive than the additive in the seed layer. In some embodiments, the additive of conductive layer 126 comprises Ta, indium (In), tin (Sn), zinc (Zn), Mn, Cr, Ti, Ge, strontium (Sr), platinum (Pt), magnesium (Mg), Al, zirconium (Zr), cobalt (Co), or other suitable additive materials.

In some embodiments, conductive layer 126 is formed by electro-chemical plating (ECP). In some embodiments, conductive layer 126 is formed by PVD, CVD or other suitable formation techniques. In some embodiments, a chemical-mechanical polishing (CMP) process is performed following formation of conductive layer 126 to planarize a top surface of IMD layer 114 with a top surface of the conductive layer.

FIG. 1C is a cross sectional diagram of wafer 100 at a third stage of production in accordance with one or more embodiments. An oxide layer 127 is formed within conductive layer 126 due to chemical oxidation reactions between the conductive layer and oxygen in an environment surrounding wafer 100. A non-limiting example of copper (Cu) as the main component of conductive layer 126 is provided below. One of ordinary skill in the art would understand the current application is applicable to materials other than copper.

When the copper of conductive layer 126 is exposed to oxygen in air or water, the oxygen reacts with the copper in an oxidation reaction to form copper oxide (CuO or Cu₂O). When Cu₂O is formed, the compound degrades to CuO in moist air. Copper oxide (CuO) has an electrical resistivity of about 100 Ωcm (ohms centimeters) to 1000 Ωcm; and copper oxide (Cu₂O) has an electrical resistivity of about 4.5×10⁵ Ωcm. In contrast, metallic copper has an electrical resistivity of 1.67×10⁻⁶ Ωcm. The increase in electrical resistance of oxide layer 127 in comparison with conductive layer 126 increases power consumption within wafer 100 and reduces a speed of circuitry in the wafer. In order to maintain low electrical resistance, oxide layer 127 is removed.

In other approaches, oxide layer 127 is removed using an in-situ plasma treatment. In-situ plasma involves introducing a gas into a chamber that houses wafer 100. The introduced gas is excited to form plasma in a same chamber that houses wafer 100. The plasma is directed toward wafer 100 and removes oxide layer 127 from conductive layer 126. However, the in-situ plasma treatment also includes the plasma ions contacting IMD layer 114 surrounding conductive layer 126. The high energy and temperature of the plasma in the in-situ plasma treatment damages IMD layer 114. The damaged IMD layer 114 experiences an increase in the dielectric constant at a damaged surface portion of the IMD layer. The increased dielectric constant results in a decrease in an ability to provide electrical insulation. The damaged IMD layer 114 also has a lower adhesion with a subsequently formed second etch stop layer 128, as seen in FIG. 1D. The lower adhesion increases the risk of peeling or lift-off between metal layers which has the potential to prevent transmission of an electrical signal between the metal layers.

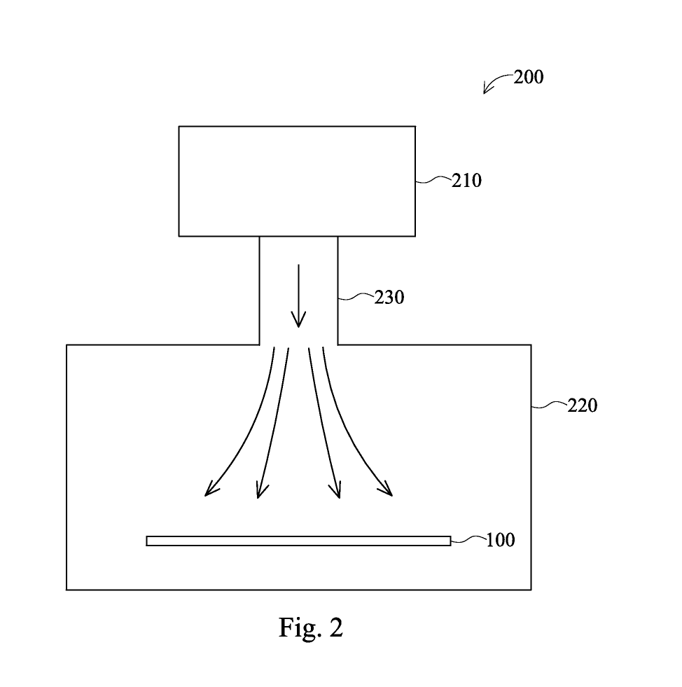

In some embodiments of the current application, oxide layer 127 is reduced using a remote plasma treatment. FIG. 2 is a schematic diagram of a remote plasma treatment apparatus 200 used to reduce a metal oxide layer on a wafer in accordance with one or more embodiments. Remote plasma treatment apparatus 200 includes a plasma generation chamber 210 separate from a process chamber 220 which houses wafer 100. A treatment gas and a carrier gas are introduced into plasma generation chamber 210. In some embodiments, the treatment gas comprises ammonia (NH₃), silane (SiH₄), methane (CH₄), hydrogen gas (H₂), phosphane (PH₄), or other suitable treatment gases. The carrier gas is an inert gas. In some embodiments, the carrier gas comprises nitrogen gas (N2), argon (Ar), helium (He), or other suitable carrier gases.

The treatment gas and carrier gas are introduced into plasma generation chamber 210 and the treatment gas is excited to create a reaction gas containing plasma. In some embodiments, the treatment gas is exited using microwaves to create the reaction gas containing plasma. The microwaves are generated using a microwave oscillator and are introduced into plasma generation chamber 210 using an optical waveguide. In some embodiments, the microwaves have a frequency of from about 13 megahertz (MHz) to about 14 MHz. In some embodiments, a radio frequency (RF) power in plasma generation chamber 210 ranges from about 1800 watts (W) to about 2600 W.

The reaction gas is then fed through a conduit 230 into process chamber 220 where wafer 100 is housed. In some embodiments, a temperature of process chamber 210 ranges from about 400° C. to about 650° C. In some embodiments, the temperature of process chamber 210 is less than or equal 450° C. In some embodiments, a pressure in process chamber 210 ranges from about 1.5 Torr to about 2.5 Torr. In some embodiments, a process time for interaction between the reaction gas and wafer 100 ranges from about 5 seconds to about 600 seconds.

The reaction gas is a reactive species of plasmarized hydrogen. The plasmarized hydrogen reacts with oxide layer 127 in a reduction reaction. Using the above example of copper oxide, the reduction reaction yields water and metallic copper. The reduction reaction will decrease the electrical resistance of a top surface of conductive layer 126 to the pre-oxidation level.

Returning to FIGS. 1A-1D, following the reduction of oxide layer 127, second etch stop layer 128 is formed over IMD layer 114 and conductive layer 126. FIG. 1D is a cross sectional diagram of wafer 100 at a fourth stage of production in accordance with one or more embodiments. Second etch stop layer 128 is formed following reduction of oxide layer 127 and creates a barrier between conductive layer 126 and the surrounding environment to prevent re-oxidation of the conductive layer. The materials and techniques used to produce second etch stop layer 128 are similar to those discussed with respect to first etch stop layer 112. In some embodiments, second etch stop layer 128 comprises a same material as first etch stop layer 112. In some embodiments, second etch stop layer 128 comprises a different material from first etch stop layer 112.

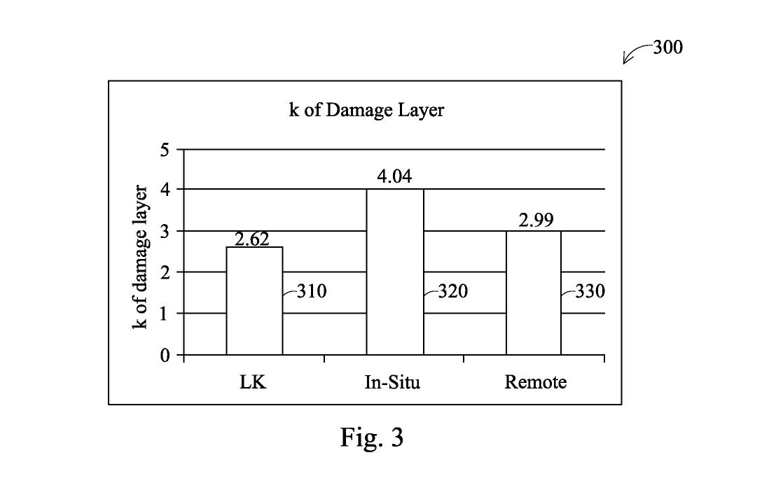

FIG. 3 is a graph 300 of a dielectric constant of an inter-metal dielectric (IMD) layer in accordance with one or more embodiments. Graph 300 includes the dielectric constant (k) of a damaged portion of an IMD layer, e.g., IMD layer 114 (FIGS. 1A-1D). In some embodiments, a depth of the damaged portion of the IMD layer is about 100 \acute{Å}. A bar 310 indicates the dielectric constant of the damaged portion of the IMD layer prior to pre-treatment to address an oxide layer, e.g., oxide layer 127 (FIG. 1C). Bar 310 shows that the dielectric constant of the IMD layer prior to pre-treatment is about 2.62. A bar 320 indicates the dielectric constant of the damaged portion of the IMD layer following an in-situ plasma treatment to remove the oxide layer. Bar 320 shows that the dielectric constant of the damaged portion of the IMD layer increased by greater than 50% from the pre-treatment dielectric constant value to about 4.04. A bar 330 indicates the dielectric constant of the damaged portion of the IMD layer following a remote plasma treatment to reduce the oxide layer. Bar 330 shows that the dielectric constant of the damaged portion of the damaged portion of the IMD layer increased by less than 15% from the pre-treatment dielectric constant value to about 2.99. The remote plasma treatment resulted in a 40% reduction in the dielectric constant with respect to the in-situ plasma treatment.

The lower dielectric constant value resulting from the remote plasma treatment means the IMD layer will have a reduced RC delay in comparison with a structure which has a structure on which in-situ plasma is performed.

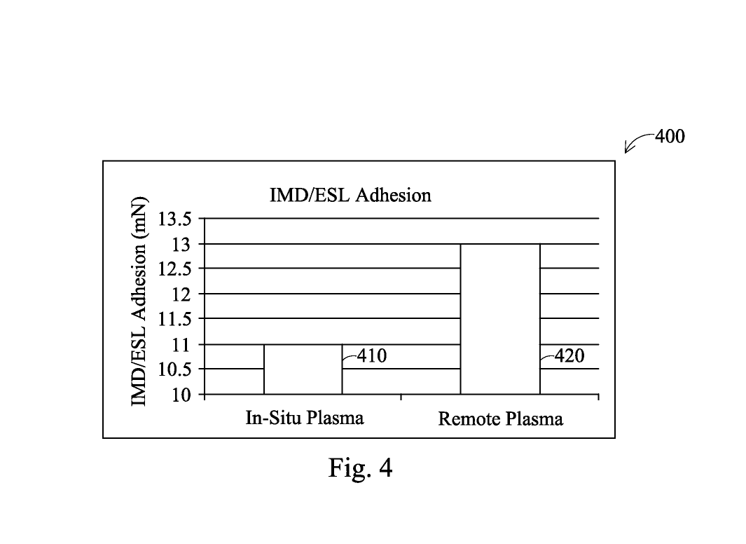

FIG. 4 is a graph 400 of an adhesion force between an IMD layer and an etch stop layer in accordance with one or more embodiments. Graph 400 indicates the adhesion force between the IMD layer, e.g., IMD layer 114, and the etch stop layer, e.g., second etch stop layer 128 (FIG. 1D), following formation of the etch stop layer after two different treatments to address the oxide layer, e.g. oxide layer 127. A bar 410 indicates an adhesion strength between the IMD layer and the etch stop layer following an in-situ plasma treatment. Bar 410 shows an adhesion strength of 11 milliNewtons (mN). A bar 420 indicates an adhesion strength between the IMD layer and the etch stop layer following a remote plasma treatment. Bar 420 shows an adhesion strength of 13 mN, a more than 18% increase with respect to the adhesion strength following the in-situ plasma treatment. The higher adhesion strength following the remote plasma treatment helps to prevent separation of the IMD layer from the etch stop layer. The reduced risk of separation increases production yield and potentially increases a longevity of the semiconductor device because the electrical connections through an interconnect structure are less likely to fail.

Further, a semiconductor device formed using a remote plasma treatment to reduce an oxide layer on the conductive layer exhibits a lower leakage current in comparison with a semiconductor device formed using an in-situ plasma treatment. The lower leakage current results from a decreased amount of damage to the IMD layer during the remote plasma treatment.

A time dependent dielectric breakdown (TDDB) of a semiconductor device formed using a remote plasma treatment to reduce an oxide layer on the conducive layer is about two orders of magnitude higher than a semiconductor device formed using an in-situ plasma treatment. The TDDB is similar to a breakdown voltage of the IMD layer. The break down voltage is the voltage at which a portion of the IMD layer becomes conductive, which prevent electrical insulation from the adjacent conductive layers.

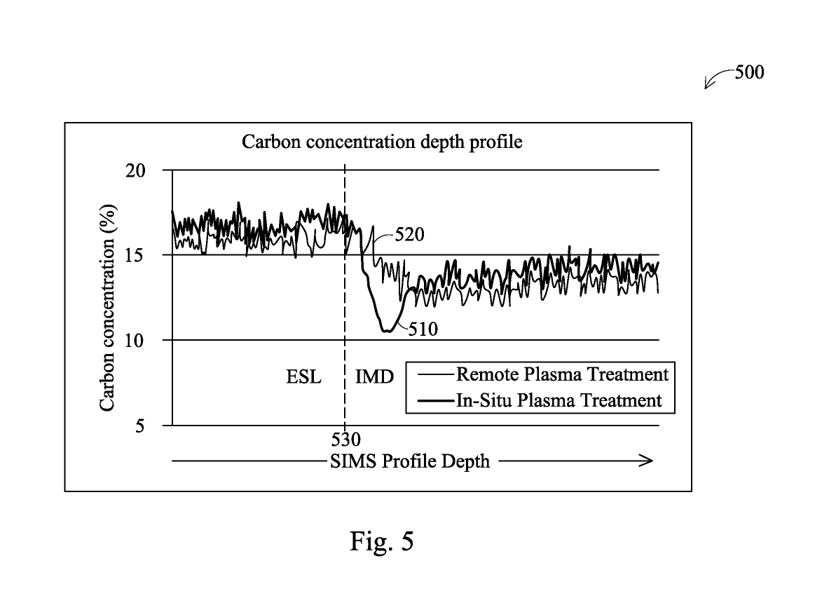

FIG. 5 is a graph 500 of a carbon concentration depth profile of a wafer in accordance with one or more embodiments. Graph 500 includes a plot 510 corresponding to a carbon concentration profile in a wafer subjected to in-situ plasma treatment. Graph 500 further includes a plot 520 corresponding to a carbon concentration profile in a wafer subjected to remote plasma treatment. A shaded portion of graph 500 is an etch stop layer, e.g., second etch stop layer 128. In the non-limiting example of FIG. 5, the etch stop layer comprises SiC. A non-shaded portion of graph 500 is an IMD layer, e.g., IMD layer 114. In the non-limiting example of FIG. 5, the IMD layer comprises SiOC.

Carbon concentration in the IMD layer helps to enhance adhesion between IMD layer 114 and second etch stop layer 128 and help to increase electromigration resistance. Electromigration is the transport of material of a conductive layer, e.g., conductive layer 126, into a surrounding material, e.g., IMD layer 114, caused by passing a current through the conductive layer. As more conductive material is dispersed into the IMD layer, the IMD layer will have a decreased ability to insulate between adjacent conductive layers. In addition, the carbon concentration helps to increase the porosity of IMD layer 114, which in turn reduces the dielectric constant k of the IMD layer to help maintain a low RC delay.

Plot 510 shows a sharp drop in the carbon concentration at a surface portion of the IMD layer below an interface 530. The drop in carbon concentration at the surface of the IMD layer falls below a core carbon concentration in the IMD layer below a surface portion of the IMD layer. The drop in surface carbon concentration results from damage to the IMD layer during the in-situ plasma treatment. The lower concentration of carbon will reduce adhesion between the IMD layer and the second etch stop layer in the IMD layer subjected to in-situ plasma treatment and result in increased electromigration in the surface portion of the IMD layer, as well as a greater RC delay.

Plot 520 shows a gradual decrease in carbon concentration from the high carbon concentration in the SiC etch stop layer to the core carbon concentration in the IMD layer. The higher carbon concentration of plot 520 relative to plot 510 is a result of a decreased amount of damage to the IMD layer during the remote plasma treatment in comparison with the damage to the IMD layer during the in-situ plasma treatment. As a result, a conductive layer formed in an IMD layer indicated by plot 520 will have a higher adhesion to the second etch stop layer and the IMD layer will have a higher resistance to electromigration in comparison with a conductive layer formed in the IMD layer indicated by plot 510.

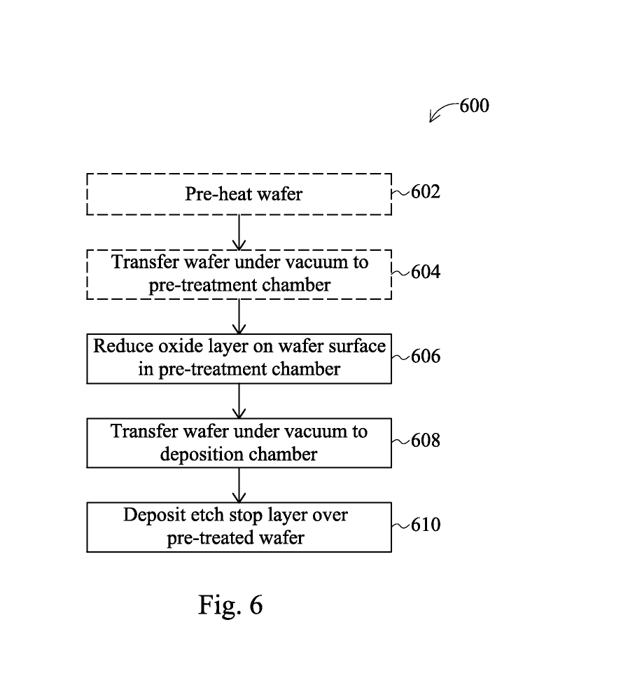

FIG. 6 is a flow chart of a method 600 of reducing a metal oxide layer on a wafer in accordance with one or more embodiments. Method 600 begins with optional operation 602 in which a wafer, e.g., wafer 100, is pre-heated. In some embodiments, the wafer is pre-heated using a pre-heating chamber configured to heat the wafer using an inert gas. In some embodiments, the wafer is heated to a temperature equal to a processing temperature. In some embodiments, the wafer is heated to a temperature below the processing temperature. The processing temperature is a temperature at which the wafer is subjected to a pre-treatment process to reduce an oxide layer, e.g., oxide layer 127, on a surface of the wafer. In some embodiments, operation 602 is omitted as a separate operation and the wafer is heated in a same operation as pre-treating the wafer. In embodiments where operation 602 is omitted, method 600 begins with operation 606.

Method 600 continues with optional operation 604 in which the wafer is transferred under a vacuum to a pre-treatment chamber. The pre-treatment chamber is the chamber in which the oxide on the surface of the wafer is reduced by a reduction reaction. The wafer is transferred under a vacuum to prevent further oxidation of a conductive layer, e.g., conductive layer 126, during the transfer process. The vacuum prevents the conductive layer from being exposed to oxygen in the surrounding environment. In some embodiments, operation 604 is omitted. Operation 604 is omitted when operation 602 is omitted. In embodiments where operation 604 is omitted, method 600 begins with operation 606.

Method 600 continues with operation 606 in which the oxide layer on the wafer surface is reduced in the pre-treatment chamber. The oxide layer is reduced by a reduction reaction in which the oxygen in the oxide layer is reacted with a reducing agent in order to remove oxygen from the oxide layer. In some embodiments, the reducing agent is generated using remote plasma and the pre-treatment chamber is a remote plasma treatment apparatus.

The remote plasma pre-treatment includes introducing a treatment gas into a plasma generation chamber. In some embodiments, a treatment gas and a carrier gas are introduced into plasma generation chamber 210. The treatment gas includes a hydrogen-containing gas. In some embodiments, the treatment gas includes ammonia (NH₃), silane (SiH₄), methane (CH₄), hydrogen gas (H₂), phosphane (PH₄), or other suitable treatment gases. In some embodiments, a flow rate for the treatment gas ranges from about 10 standard cubic centimeters per minute (sccm) to about 1000 sccm. The carrier gas is an inert gas. In some embodiments, the carrier gas comprises nitrogen gas (N2), argon (Ar), helium (He), or other suitable carrier gases. In some embodiments, a flow rate of the carrier gas ranges from about 10 sccm to about 30000 sccm.

The treatment gas is excited in the plasma generation chamber to form a reaction gas, which is introduced into a process chamber housing the wafer. The reaction gas reacts with the oxide layer on the wafer in a reduction reaction.

Following the pre-treatment, the wafer is substantially free of the oxide layer. Method 600 continues with operation 608 in which the wafer is transferred under vacuum to a deposition chamber. The wafer is transferred under vacuum to prevent the oxide layer from reforming on the wafer due to exposure of the conductive layer to oxygen. In some embodiments, the pre-treatment chamber, transferring apparatus and deposition chamber are all part of an integrated structure which is sealed with respect to the outside environment.

Method 600 continues with operation 610 in which an etch stop layer is formed over the pre-treated wafer. The etch stop layer, e.g., second etch stop layer 128, effectively seals the conductive layer of the wafer by shielding the conductive layer from a surrounding environment and preventing oxygen from contacting the conductive layer.

One of ordinary skill in the art would understand method 600 includes additional steps, in some embodiments. One of ordinary skill in the art would further understand method 600 is repeated several times during the formation of a semiconductor device, in some embodiments.

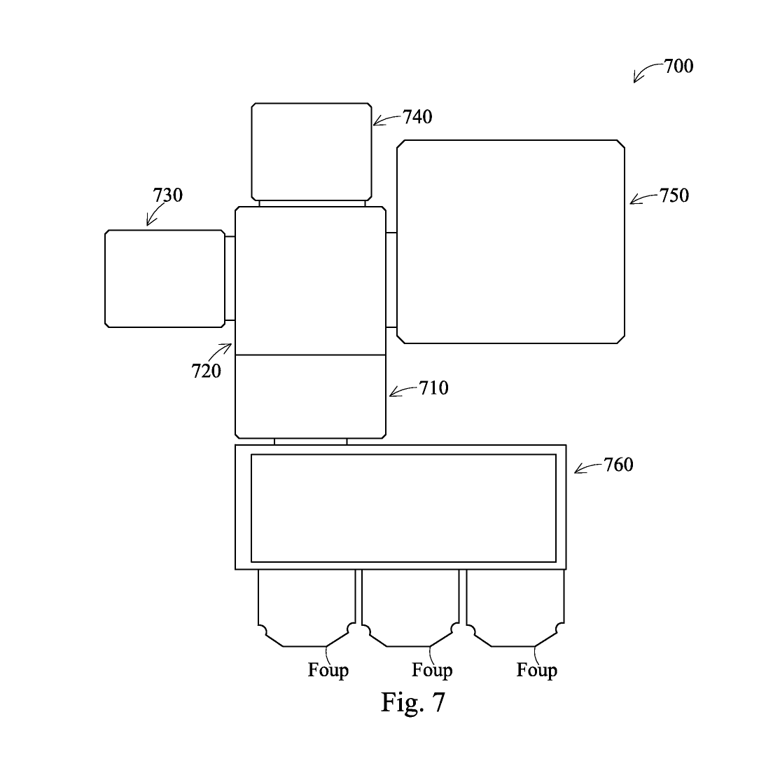

FIG. 7 is a block diagram of an apparatus 700 for implementing the method of FIG. 6 in accordance with one or more embodiments. Apparatus 700 includes a loading port 710 configured to receive a wafer. Apparatus 700 further includes a transfer module 720 configured to transfer the wafer between different modules within apparatus 700. Apparatus 700 further includes a pre-heating module 730 configured to pre-heat the wafer. Apparatus 700 further includes a pre-treatment module 740 configured to reduce an oxide layer on the wafer. Apparatus 700 further includes a deposition module 750 configured to form an etch stop layer on the pre-treated wafer. Apparatus 700 also includes a loading module 760 configured to insert and remove wafers from loading port 710.

Loading port 710 is configured to receive a wafer from loading module 760. Loading port 710 comprises a door positioned at an interface with loading module 760. The door is opened during loading or unloading processes. In some embodiments, following the loading or unloading process, the door is sealed and an inside of apparatus 700 is vacuumed out.

Transfer module 720 is configured to transfer wafers from one module in apparatus 700 to another module. In some embodiments, transfer module 720 comprises a seal between loading port 710 and the transfer module to prevent oxygen from entering the transfer module during the loading or unloading process. By preventing oxygen from entering transfer module 720, the risk of further oxidation of a conductive layer on a wafer is reduced.

Pre-heating module 730 is configured to receive the wafer from transfer module 720 and pre-heat the wafer. Pre-heating module 730 is configured to pre-heat the wafer by flowing a heated inert gas over the wafer. In some embodiments, the inert gas comprises nitrogen gas (N₂), argon (Ar), helium (He), or other suitable inert gases. In some embodiments, pre-heating module 730 is configured to pre-heat the wafer to a processing temperature of pre-treatment module 740. In some embodiments, pre-heating module 730 is configured to pre-heat the wafer to a temperature below the processing temperature of pre-treatment module 740. Following pre-heating in pre-heating module 730, the wafer is returned to transfer module 720 and remains under a vacuum to prevent further oxidation of a conductive layer on the wafer.

Pre-treatment module 740 is configured to receive the wafer from transfer module 720 and remove the oxide layer from the wafer by a reduction reaction. In some embodiments, pre-treatment module 740 is similar to remote plasma treatment apparatus 200 (FIG. 2). In some embodiments where pre-heating module 730 is omitted or the pre-heating module is configured to pre-heat the wafer to a temperature lower than a processing temperature of pre-treatment module 740, the pre-treatment module is configured to heat the wafer prior to removing the oxide layer. Following removal of the oxide layer, the wafer is returned to transfer module 720 and remains under a vacuum to prevent re-oxidation of the conductive layer on the wafer.

Deposition module 750 is configured to receive the wafer from transfer module 720 and form an etch stop layer on the wafer. The etch stop layer covers the conductive layer on the wafer and shields the conductive layer from contact with oxygen. In some embodiments, deposition module is a CVD chamber, a PECVD chamber, or another suitable deposition chamber. Following formation of the etch stop layer, the wafer is returned to transfer module 720 under vacuum and returned to loading port 710 for unloading. In some embodiments, deposition module 750 has a separate unloading port configured to remove the wafer from the deposition module without returning the wafer to transfer module 720.

Loading module 760 is configured to load and unload wafer from the loading port 710. Loading module 760 includes a wafer moving apparatus configured to insert and remove wafers from loading port 710. In some embodiments, wafer moving apparatus comprises a robotic arm or other suitable apparatus. Loading module 760 further includes docking locations configured to receive front opening universal pods (FOUPs). FOUPs are used to transport wafers between different devices during the production process.

In some embodiments, the use of the remote plasma treatment to reduce the metal oxide layer on the interconnect reduces damage to the IMD layer surrounding the interconnect structure. As a result, the dielectric constant of the IMD layer remains lower than in processes which use an in-situ plasma treatment. The decreased damage to the IMD layer also helps to maintain a higher carbon concentration in a surface region of the IMD layer and promote better adhesion between the IMD layer and subsequently formed layers. In some embodiments, maintaining the wafer under a vacuum condition during processing prevents oxygen from contacting the conductive material of the interconnect which prevents additional oxidation or re-oxidation following the remote plasma treatment.

One aspect of this description relates to a method of forming a semiconductor device. The method includes forming an interconnect structure on a wafer, wherein the interconnect structure comprises a metal oxide layer on a top surface thereof. The method further includes performing a remote plasma treatment on the wafer to reduce the metal oxide layer of the interconnect structure by a reduction reaction. The method further includes forming a dielectric layer over the wafer, wherein the semiconductor device and maintaining the semiconductor device under a vacuum condition, wherein the semiconductor device is maintained under a vacuum condition following the remote plasma treatment until the dielectric layer is formed.

Another aspect of this description relates to a method of forming a semiconductor device in an integrated system. The method includes forming a conductive layer on a wafer and pre-heating the wafer. The method further includes performing a remote plasma treatment on the wafer, in a first module of the integrated system, to remove a metal oxide layer from the conductive layer by a reduction reaction. The method further includes transferring the wafer from the first module to a second module of the integrated system under a vacuum condition and forming a dielectric layer, in the second module, over the conductive layer.

Still another aspect of this description relates to a semiconductor device. The semiconductor device includes a substrate and an inter-metal dielectric (IMD) layer formed on the substrate, wherein the IMD layer is a continuous layer. The semiconductor device further includes a conductive layer formed in the IMD layer and an etch stop layer over the IMD layer and the conductive layer, the etch stop layer has a dielectric constant equal to or greater than 4. A surface portion of the IMD layer has a higher dielectric constant than a portion of the IMD layer distal from the etch stop layer, and the surface portion of the IMD layer has a dielectric constant of less than 3.0.

It will be readily seen by one of ordinary skill in the art that the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A method of forming a semiconductor device, the method comprising:
forming an interconnect structure on a wafer, wherein the interconnect structure comprises a metal oxide layer on a top surface thereof;
performing a remote plasma treatment on the wafer to reduce the metal oxide layer of the interconnect structure by a reduction reaction;
forming a dielectric layer over the wafer; and
maintaining the semiconductor device under a vacuum condition, wherein the semiconductor device is maintained under a vacuum condition following the remote plasma treatment until the dielectric layer is formed.

2. The method of claim 1, further comprising:
pre-heating the wafer prior to performing the remote plasma treatment.

3. The method of claim 2, wherein the semiconductor device is maintained under a vacuum condition following pre-heating the wafer until the dielectric layer is formed.

4. The method of claim 1, wherein performing remote plasma treatment on the wafer comprises:
generating a hydrogen-containing reaction gas in a plasma generation chamber separate from a process chamber housing the wafer;
transferring the reaction gas, using a conduit, to the process chamber; and
reducing the oxide layer on the wafer using the hydrogen-containing reaction gas.

5. The method of claim 4, wherein generating the hydrogen-containing reaction gas comprises:
introducing a treatment gas at a first flow rate into the plasma generation chamber, the treatment gas comprising at least one of ammonia (NH₃), silane (SiH₄), methane (CH₄), hydrogen gas (H₂), or phosphane (PH₄); and
exciting the treatment gas to generate the reaction gas.

6. The method of claim 5, wherein exciting the treatment gas comprises introducing microwaves into the plasma generation chamber.

7. The method of claim 4, wherein reducing the oxide layer on the wafer comprises reducing the oxide layer at a pressure ranging from about 1.5 Torr to about 2.5 Torr.

8. The method of claim 1, wherein performing the remote plasma treatment on the wafer raises a dielectric constant of a surface portion of a dielectric material surrounding the oxide layer, and the surface portion having the raised dielectric constant less than 3.0.

9. The method of claim 1, wherein performing the remote plasma treatment on the wafer maintains a carbon concentration in an entirety of a surface portion of a dielectric material surrounding the oxide layer at a concentration equal to or greater than a core carbon concentration of the dielectric material.

10. A method of forming a semiconductor device in an integrated system, the method comprising:
forming a conductive layer on a wafer;
pre-heating the wafer;
performing a remote plasma treatment on the wafer, in a first module of the integrated system, to remove a metal oxide layer from the conductive layer by a reduction reaction;
transferring the wafer from the first module to a second module of the integrated system under a vacuum condition; and
forming a dielectric layer, in the second module, over the conductive layer.

11. The method of claim 10, wherein performing the remote plasma treatment comprises:
introducing a treatment gas at a first flow rate into a plasma generation chamber, the treatment gas comprising at least one of ammonia (NH₃), silane (SiH₄), methane (CH₄), hydrogen gas (H₂), or phosphane (PH₄);
introducing a carrier gas at a second flow rate into the plasma generation chamber, the carrier gas comprising at least one of nitrogen gas (N₂), argon (Ar), or helium (He); and
exciting the treatment gas to generate a reaction gas for reducing the oxide layer.

12. The method of claim 10, further comprising transferring the wafer from a third module of the integrated system to the first module under a vacuum condition, wherein pre-heating the wafer occurs in the third module.

13. The method of claim 10, wherein performing the remote plasma treatment raises a dielectric constant of a surface portion of a dielectric material surrounding the oxide layer, and the surface portion having the raised dielectric constant is less than 3.0.

14. The method of claim 10, wherein performing the remote plasma treatment maintains a carbon concentration in an entirety of a surface portion of a dielectric material surrounding the oxide layer at a concentration equal to or greater than a core carbon concentration of the dielectric material.

15. The method of claim 10, wherein pre-heating the wafer occurs in the first module.

16-20. (canceled)

21. A method of forming a semiconductor device, the method comprising:
performing a remote plasma treatment on a wafer, wherein the wafer comprises an interconnect structure comprising a metal oxide layer, and the remote plasma treatment reduces the metal oxide layer by a reduction reaction;
forming a dielectric layer over the reduced metal oxide layer; and
maintaining the wafer under a vacuum condition following the remote plasma treatment until the dielectric layer is formed.

22. The method of claim 21, wherein performing the remote plasma treatment comprises performing the remote plasma treatment on a surface of an inter-metal dielectric (IMD) layer surrounding the interconnect structure.

23. The method of claim 21, wherein performing the remote plasma treatment comprises plasmarizing a hydrogen-containing treatment gas in a plasma generation chamber separated from the wafer by a conduit.

24. The method of claim 23, wherein plasmarizing the hydrogen-containing treatment gas comprises plasmarizing at least one of ammonia (NH₃), silane (SiH₄), methane (CH₄), hydrogen gas (H₂), or phosphane (PH₄).

25. The method of claim 21, wherein maintaining the wafer under the vacuum condition comprises maintaining the wafer under the vacuum condition while transferring the wafer from a first module to a second module, the remote plasma treatment being performed in the first module, and the dielectric layer being formed in the second module.
